(19) United States
(12) Patent Application Publication
(10) Pub. No.: US 2016/0322350 A1
(43) Pub. Date: Nov. 3, 2016

(54) Geometry for a Bidirectional Bipolar Transistor with Trenches that Surround the Emitter/Collector Regions

(71) Applicant: Ideal Power Inc., Austin, TX (US)

(72) Inventor: Richard A. Blanchard, Los Altos, CA (US)

(73) Assignee: Ideal Power Inc., Austin, TX (US)

(21) Appl. No.: 15/083,230

(22) Filed: Mar. 28, 2016

Related U.S. Application Data
(60) Provisional application No. 62/139,380, filed on Mar. 27, 2015.
(60) Provisional application No. 62/139,407, filed on Mar. 27, 2015.

(51) Int. Cl. H01L 27/06; H01L 29/735; H01L 23/535; H01L 29/40; H01L 29/08; H01L 29/06

(52) U.S. Cl. CPC H01L 27/0694; H01L 29/0808; H01L 29/0821; H01L 29/0649; H01L 23/535; H01L 29/0619; H01L 29/407; H01L 29/405; H01L 29/404; H01L 29/735

(57) ABSTRACT

Bidirectional symmetrically-bidirectional power bipolar devices are laid out so that each emitter/collector region, on either side of the die, is laterally surrounded entirely by trenches which preferably contain insulated field plates, and which prevent lateral propagation of carriers. Most preferably the emitter/collector regions are laid out as stripes, so no part of the emitter/collector region is unexpectedly far from a good low-resistance connection to the base contact.

### CROSS-REFERENCE

Priority is claimed from US provisional applications 62/139,407 and 62/139,380, both of which are hereby incorporated by reference.

### BACKGROUND

The present application relates to bidirectional bipolar transistors which have separate base contact regions, as well as separate emitter/collector diffusions, on both surfaces of a monolithic semiconductor die.

Note that the points discussed below may reflect the hindsight gained from the disclosed inventions, and are not necessarily admitted to be prior art.

Bi-directional bipolar transistors or “B-TRANs” have been proposed for use as high voltage bi-directional switches, based on their low on-voltages at high current levels. One concern in the actual fabrication of a high voltage B-TRAN is the design of a termination structure capable of withstanding the rated voltage without significantly increasing the cost of the device. A number of possible high voltage termination structures exist, but the goal of this work was to determine whether there are any high voltage termination structures that can be fabricated using the same process steps as those used to fabricate the B- TRAN structure. The structure of an NPN B-TRAN device is shown in FIG. 1B while one possible circuit symbol for this device is shown in FIG. 2.

An enhancement to the B-TRAN structure of FIG. 1B is shown in FIG. 3. In this figure, the trench that was filled with dielectric in FIG. 1B has a trench lined with a dielectric like silicon dioxide, and is subsequently filled with conductive polycrystalline silicon. The polycrystalline silicon electrode located in each trench is in turn electrically connected to the n-type emitter diffusion region present on at least one side of the trench.

FIG. 4 shows a cross section of a B-TRAN device, including a portion of the termination region of the structure.

A Geometry for a Bidirectional Bipolar Transistor with Trenches that Surround the Emitter/Collector Regions

The present application teaches, among other innovations, a layout for the emitter/collector and base contact regions on either surface of a semiconductor die, which in combination provide a symmetrically-bidirectional bipolar transistor. The emitter/collector regions (doped e.g. n+) are surrounded by trenches which preferably contain insulated field plates, and which prevent lateral propagation of carriers.

The preferred geometry advantageously reduces lateral parasitic resistance between the center of the emitter/collector and the nearest base contact region. This not only provides benefits for fabrication, but also increases injection efficiency.

Preferably, but not necessarily, the trenches around the emitter/collector region contain insulated field plates.

Preferably, but not necessarily, the emitter/collector regions are laid out in a stripe geometry.

Optionally but advantageously, the emitter/collector regions (e.g. n+) are laid out in a stripe geometry, and the fully doped base contact region (e.g. p+) abuts both sides of each stripe of the emitter/collector regions, while a more lightly doped base region abuts the ends of the stripes of the emitter/collector regions.

Advantageously and most preferably, each of the emitter/collector regions (doped first-conductivity-type, e.g. n+) is fully surrounded by a first trench which prevents lateral conduction; the first trench is completely surrounded by a base contact region (doped p+), possibly augmented by a p-type base region; and the base contact regions (doped p+), with its augmenting p-type base region if present, is fully surrounded by a second trench which also prevents lateral conduction.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1A shows corresponding plan and section views of a new B-TRAN device.

FIG. 1B shows the structure of an example of a B-TRAN device.

FIG. 2 shows a possible circuit symbol for the device of FIG. 1B.

FIG. 3 shows an enhancement to the B-TRAN structure of FIG. 1B.

FIG. 4 shows a cross section of a B-TRAN device, including a portion of the termination region of the structure.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

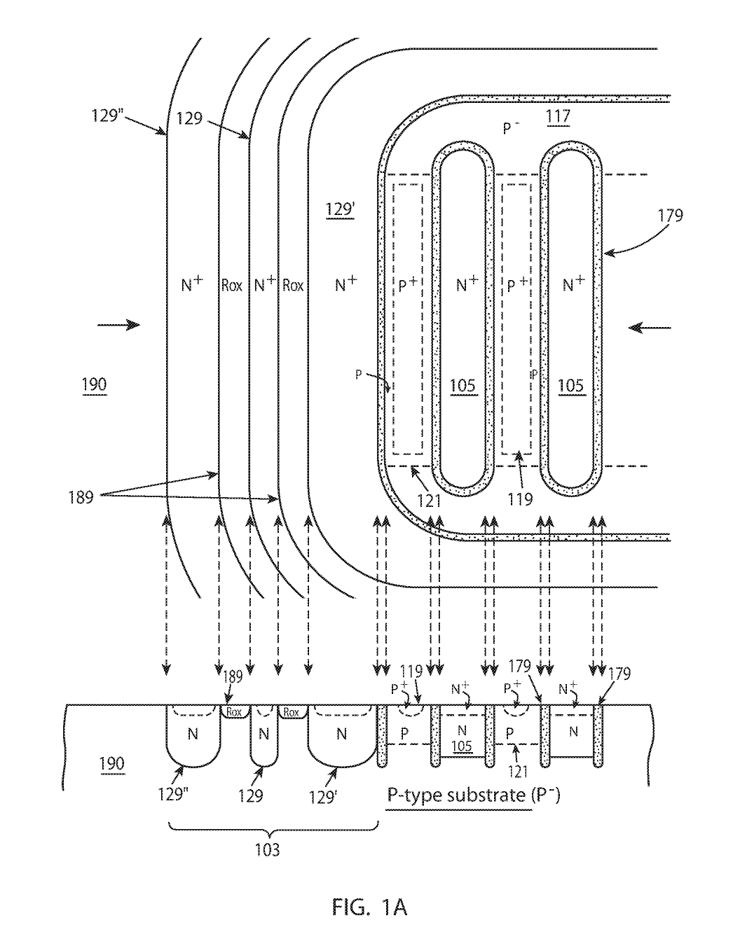

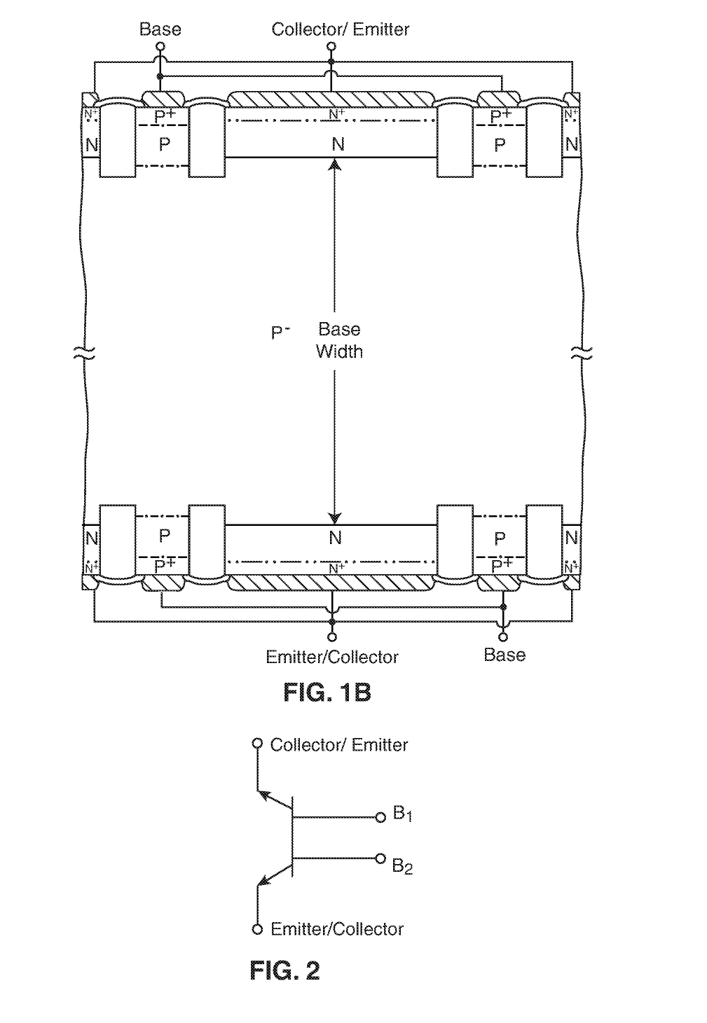

FIG. 1A shows a top view of the B-TRAN device as well as a cross section of the device. FIG. 1A shows that the termination region 103 uses the same diffused regions that form the emitter/collector regions of the B-TRAN. Specifically:

1. The diffused field-limiting rings 129 are formed by the same doping and diffusion steps as the B-TRAN emitter/collector regions 105. The use of diffused regions formed by the same step reduces the number of steps in the fabrication sequence.

2. Both the emitter regions 105 and the diffused n-type regions that form the field-limiting rings 129 preferably include both deep and shallow n-type doping components, formed by implanting both phosphorus and arsenic into the p-type substrate using the same mask. This process sequence saves the use of one masking layer, while also providing a deep n-type junction capable of withstanding a high voltage, as well as a shallow, heavily doped n++ region at the surface that forms a low resistance ohmic contact with the metal layer.

In one example, the two n-type dopants are phosphorus and arsenic, and each is implanted at a dose of 2 or 3×10¹⁵ cm⁻². Arsenic will have a shorter diffusion length than phosphorus (in silicon, for a given thermal history), so that the emitter/collector regions have both a high concentration at shallow depths, and a reasonably large junction depth.

Optionally an additional shallow n++ “plug” implant can be used to minimize specific contact resistance.

Optionally antimony can be substituted for arsenic if desired.

The example shown in FIG. 1A includes, among the field-limiting rings 129, an innermost field-limiting ring 129′ and an outermost field-limiting ring 129″. For clearer illustration, only three field-limiting rings 129 are shown in FIG. 1A, but this is simplified. In a currently preferred example, ten field-limiting rings 129 are used, including eight rings 129 between the innermost field-limiting rings 129′ and the outermost field-limiting ring 129″.

In this example, the widest one of the field-limiting rings 129 is the innermost field-limiting ring 129′. The outermost field-limiting ring 129″ is also wider than the other ones of the field-limiting rings 129.

In this example, recessed oxide regions 189 (“Rox”) are interposed between adjacent field limiting rings 129. Recessed oxide regions 189 can be formed using a “LOCOS” process, or alternatively by etching a trench, filling with oxide, and then planarizing the wafer using CMP. For example, this can be done by etching about ½ micron of silicon, growing about 1.1 micron of SiO₂, and then planarizing using CMP.

Another way to form the recessed oxide regions 189 is by etching trenches to the full desired depth of the recessed oxide regions 189 (here about 1.1 microns deep), filling the trenches using a TEOS oxide, using a modified reverse mask to remove most of the deposited oxide that is not over the trenches, and then using CMP to planarize the wafer.

In both these examples (but not necessarily in every implementation), the recessed oxide regions 189 are not associated with the field plates which can be emplaced in the trenches 179. The field plates are formed of poly silicon, later in the process.

The thickness of the recessed oxide regions 189, in this example, is selected to be slightly more than a micron. Smaller thickness values can degrade the long term reliability of the device.

Another criterion for optimization of this particular process is local planarity. Since a handle wafer will be bonded to each side of the wafer (in the preferred process), the recessed oxide regions 189 need to be planar, to avoid degrading bondability.

Another criterion for optimization of this particular process is wafer flatness. The process of forming the recessed oxide regions 189 should not impart warping or bowing of the wafer (as may be caused by accumulation of stress from local pattern features).

Note also, in FIG. 1A, that each emitter/collector region 105 is shaped like a stripe, and is bordered, along its long sides, by a p+ base contact region 119 inside p-type base contact border region 121. The short side of each emitter/collector region 105 is bordered by p− base region 117. This is useful in optimizing the emitter/collector regions to have uniform turnoff, and to have fairly uniform on-state current density across their width.

The dopant profile of the base contact regions 119 is preferably formed by several diffusion components. The background wafer doping, in this example, is p-type. In addition, two implantations of boron and/or boron difluoride dopants are used, in a preferred example, to achieve good contact resistance and reduce the series resistance from the contact area to the p-type substrate. The total p-type doping introduced into the base contact areas 119, in this example, is around 2×10¹⁵ cm⁻².

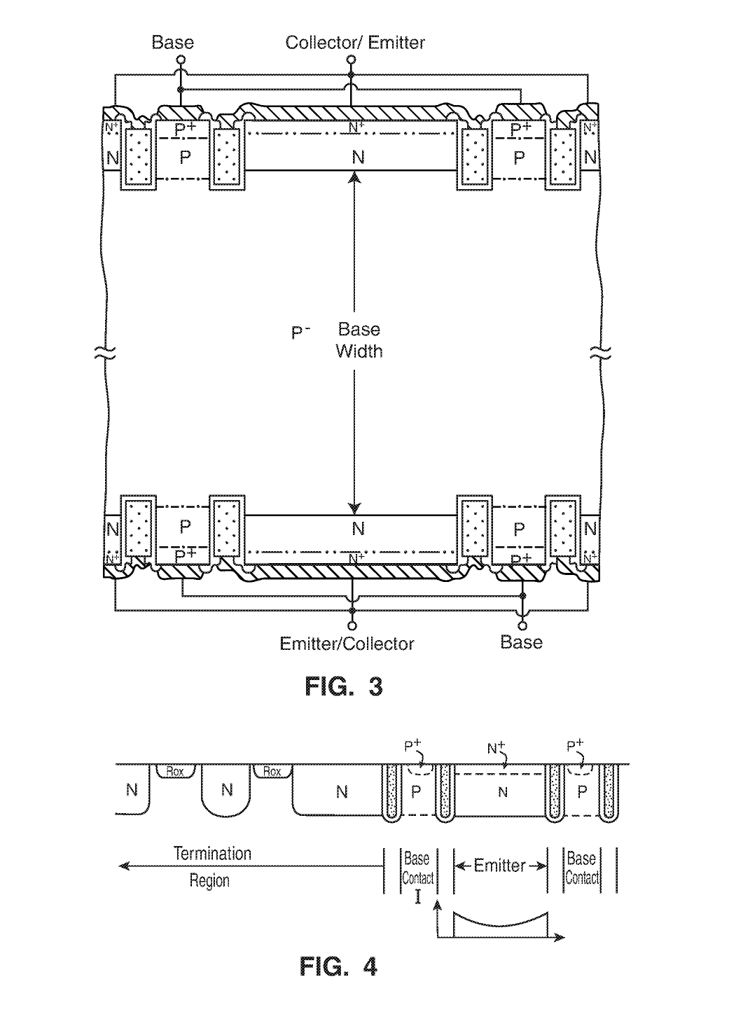

The base-to-emitter/collector isolation trenches 179, in this example, can include insulated polysilicon field plates which are electrically connected to the adjacent n-type emitter/collector region. However, other separation structures can be used, e.g. dielectric-filled trenches as shown in FIG. 3.

Note also that, in FIG. 4, the shallowest p++ diffusion stops short of borders of the base contact area 119. This keeps the lateral tail of the base contact doping from modifying the doping of the field plate in the trench 179. The p− regions are simply the doped substrate; the p regions have been implanted and diffused to about 3 microns; and the P+ regions are doped by an implant performed through the contact mask opening, to assure a low contact resistance to the P region. Thus in this example the p+ regions are set back from the poly field plate, while the p regions are not.

FIG. 1A also shows inventive features which allow for efficient mobile carrier injection when the N+/N− emitter/collector regions on one surface are forward biased (thereby acting as the emitter), and provide a high breakdown voltage when the same regions are reverse biased (and acting as the collector).

1. Each emitter/collector region is completely surrounded by a trench that has a liner of a dielectric layer or a dielectric sandwich and is filled with doped polycrystalline silicon. An electrical connection is also made between the polycrystalline silicon in the trench and the emitter region.

2. There is P+ dopant adjacent to the trench along the majority of its two straight sides. The presence of the P+ dopant in these regions provides a low resistance path to the portion of the base contact region adjacent to the emitter/collector region, thereby decreasing the base resistance. The p+ region can also be extended to completely surround the racetrack, filling the entire region between the racetracks and the poly-filled perimeter trench. (The perimeter poly-filled trench provides a transition region between the interior “active” region of the B-TRAN and the edge termination region.)

### Advantages

The disclosed innovations, in various embodiments, provide one or more of at least the following advantages. However, not all of these advantages result from every one of the innovations disclosed, and this list of advantages does not limit the various claimed inventions.
Avoidance of hot spots in the ON state;
Stable and uniform turn-off;
Ability to switch high voltages.

According to some but not necessarily all embodiments, there is provided: A symmetrically-bidirectional power bipolar transistor device, comprising: a semiconductor die having, on both surfaces thereof, a first-conductivity-type emitter/collector region which is completely laterally surrounded by a first insulating trench, and which overlies a second-conductivity-type semiconductor mass; two current-carrying metallizations, on the two surfaces of the die, which separately connect the two emitter/collector regions to respective external current-carrying terminals, but not to each other; one or more second-conductivity-type base contact regions, including heavily-doped second-conductivity-type contact areas, which border and completely surround the first insulating trench; two additional metallizations, on the two surfaces of the die, which separately connect the two base contact regions to respective additional external terminals, but not to each other; one or more second insulating trenches, which, singly or in combination, completely surround the second-conductivity-type base contact regions; an innermost first-conductivity-type field-limiting ring, which completely surrounds the second insulating trenches; and additional first-conductivity-type field-limiting rings, which surround the innermost field-limiting ring.

According to some but not necessarily all embodiments, there is provided: A symmetrically-bidirectional power bipolar transistor device, comprising: a semiconductor die having, on both surfaces thereof, a first-conductivity-type emitter/collector region which is completely surrounded by a first recessed field plate; two current-carrying metallizations, on the two surfaces of the die, which separately connect the two emitter/collector regions to respective external current-carrying terminals, but not to each other; a second-conductivity-type base contact region, including heavily-doped second-conductivity-type contact areas, which closely borders and completely surrounds the first recessed field plate; two additional metallizations, on the two surfaces of the die, which separately connect the two base contact regions to respective additional external terminals, but not to each other; a second recessed field plate trench, which borders and completely surrounds the second-conductivity-type base contact region; and an innermost first-conductivity-type field-limiting ring, which completely surrounds the second recessed field plate trench.

According to some but not necessarily all embodiments, there is provided: Bidirectional symmetrically-bidirectional power bipolar devices are laid out so that each emitter/collector region, on either side of the die, is laterally surrounded entirely by trenches which preferably contain insulated field plates, and which prevent lateral propagation of carriers. Most preferably the emitter/collector regions are laid out as stripes, so no part of the emitter/collector region is unexpectedly far from a good low-resistance connection to the base contact.

According to some but not necessarily all embodiments, there is provided: a layout for the emitter/collector and base contact regions on either surface of a semiconductor die, which in combination provide a symmetrically-bidirectional bipolar transistor. The emitter/collector regions (doped e.g. n+) are surrounded by trenches which preferably contain insulated field plates, and which prevent lateral propagation of carriers.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

What is claimed is, among others (and, without exclusion, in addition to any other points which are indicated herein as inventive and/or surprising and/or advantageous):

1. A symmetrically-bidirectional power bipolar transistor device, comprising:
a semiconductor die having, on both surfaces thereof, a first-conductivity-type emitter/collector region which is completely laterally surrounded by a first insulating trench, and which overlies a second-conductivity-type semiconductor mass;
two current-carrying metallizations, on the two surfaces of the die, which separately connect the two emitter/collector regions to respective external current-carrying terminals, but not to each other;
one or more second-conductivity-type base contact regions, including heavily-doped second-conductivity-type contact areas, which border and completely surround the first insulating trench;
two additional metallizations, on the two surfaces of the die, which separately connect the two base contact regions to respective additional external terminals, but not to each other;
one or more second insulating trenches, which, singly or in combination, completely surround the second-conductivity-type base contact regions;
an innermost first-conductivity-type field-limiting ring, which completely surrounds the second insulating trenches; and
additional first-conductivity-type field-limiting rings, which surround the innermost field-limiting ring.

2. The device of claim 1, wherein the emitter/collector region defines a junction therebeneath, and the base contact regions have a depth similar to that of the emitter/collector regions.

3. The device of claim 1, wherein the die is silicon.

4. The device of claim 1, wherein the first conductivity type is n-type.

5. The device of claim 1, wherein the insulating trenches have insulated field plates therein.

6. The device of claim 1, comprising more than six of the first-conductivity-type field-limiting rings.

7. A symmetrically-bidirectional power bipolar transistor device, comprising:
a semiconductor die having, on both surfaces thereof, a first-conductivity-type emitter/collector region which is completely surrounded by a first recessed field plate;
two current-carrying metallizations, on the two surfaces of the die, which separately connect the two emitter/collector regions to respective external current-carrying terminals, but not to each other;
a second-conductivity-type base contact region, including heavily-doped second-conductivity-type contact areas, which closely borders and completely surrounds the first recessed field plate;
two additional metallizations, on the two surfaces of the die, which separately connect the two base contact regions to respective additional external terminals, but not to each other;
a second recessed field plate trench, which borders and completely surrounds the second-conductivity-type base contact region; and
an innermost first-conductivity-type field-limiting ring, which completely surrounds the second recessed field plate trench.

8. The device of claim 7, wherein the emitter/collector region defines a junction therebeneath, and the base contact regions have a depth similar to that of the emitter/collector regions.

9. The device of claim 7, wherein the wafer is silicon.

10. The device of claim 7, wherein the first conductivity type is n-type.

11. The device of claim 7, comprising more than six of the first-conductivity-type field-limiting rings.
